(19) United States
(12) Patent Application Publication
(10) Pub. No.: US 2008/0204133 A1
(43) Pub. Date: Aug. 28, 2008

(54) Circuits and apparatus to reduce transient output noise in an audio amplifier

(76) Inventors: Paul A. Fontaine, Plano, TX (US); Sachin Ranganathan, Dallas, TX (US); Rajkumar Jayaraman, Plano, TX (US)

Correspondence Address: TEXAS INSTRUMENTS INCORPORATED, P O BOX 655474, M/S 3999, DALLAS, TX, 75265, US

(21) Appl. No.: 11/712,050

(22) Filed: Feb. 28, 2007

Related U.S. Application Data
(60) Provisional application No. 60/903,229, filed on Feb. 23, 2007.

(51) Int. Cl. H03F 3/45

(52) U.S. Cl. 330/69; 381/94.5

(57) ABSTRACT

Circuits and apparatus to reduce transient output noise in an audio amplifier are disclosed. A disclosed example apparatus comprises an amplifier, and an amplifier controller to digitally change a common-mode voltage of the amplifier to reduce an output noise of the amplifier.

### RELATED APPLICATIONS

This patent claims priority from U.S. Provisional Application Ser. No. (Attorney Docket No. TI-62165PS), entitled “DAC-Based Pop-Noise Elimination Circuits for Audio Output Drivers,” filed on Feb. 23, 2007, and which is hereby incorporated by reference in its entirety.

### FIELD OF THE DISCLOSURE

This disclosure relates generally to audio amplifiers, and, more particularly, to circuits and apparatus to reduce transient output noise in an audio amplifier.

### BACKGROUND

In many audio devices (e.g., cellular telephones, MP3 players, etc.) the earpiece, headset and/or hands-free speaker(s) require the use of relatively high power signals (e.g., relatively high voltages and/or currents). Unfortunately, every time the driver (e.g., amplifier) powering these loads is powered on and/or powered off, the output (e.g., current and/or voltage) of the driver may spike temporarily. Because the human ear is sensitive to sound pressure level changes as small as zero dBspl (sound pressure level in decibels) within the audio band (e.g., 20 cycles per second (Hz) to 20 thousand Hz (kHz)), voltage spikes as small as one millivolt (mV) may cause perceptible and/or audible pop and/or click sounds (i.e., audible glitches). Additionally, voltage offsets present at the driver (e.g., between a digital-to-analog converter (DAC) and the driver) may also cause audible glitches.

### BRIEF DESCRIPTION OF THE DRAWINGS

FIG. 1 is a schematic diagram of example audio output driver constructed in accordance with the teachings of the invention.

FIG. 2 illustrates an example operation of the example audio output driver of FIG. 1.

FIG. 3 is a schematic diagram of example manner of implementing the example audio output driver of FIG. 1.

FIG. 4 is a schematic diagram of another example manner of implementing the example audio output driver of FIG. 1.

FIG. 5 illustrates an example operation of the example switch of FIG. 4.

FIG. 6 is a schematic diagram of yet another example manner of implementing the example audio output driver of FIG. 1.

FIG. 7 is a schematic diagram of an example manner of implementing any or all of the example digital-to-analog (DAC) converters of FIGS. 2, 4 and/or 6.

FIG. 8 illustrates an example output signal of the example audio output drivers of FIGS. 1, 3, 4 and/or 7 as the audio output driver is powered on.

### DETAILED DESCRIPTION

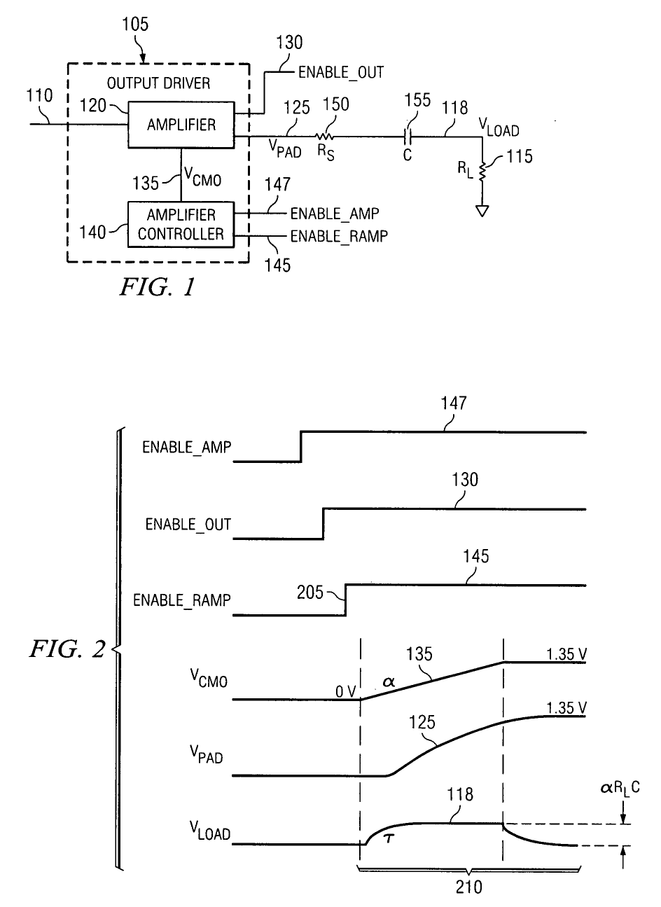

Audio output drivers are commonly used in audio devices (e.g., cellular phones, MP3 players, etc.) to amplify audio signals to a signal level suitable to facilitate listening and/or playback via, for example, a speaker and/or ear-piece(s). FIG. 1 is a schematic illustration of an example audio output driver 105 that may be used to amplify and/or drive an audio input signal 110 into a load 115 (e.g., a speaker, and/or an ear-piece). To amplify the audio input signal 110, the example audio output driver 105 of FIG. 1 includes an amplifier 120. Using any circuit(s), device(s) and/or component(s), the example amplifier 120 of FIG. 1 amplifies the audio input signal 110, and drives the amplified signal V_{pad} 125 into the load 115 to form a load voltage V_{load} 118. The example amplified signal V_{pad} 125 of FIG. 1 is an audio signal and/or waveform that includes a common-mode voltage of, for example, 1.35 volts (V). To power on and power off the example amplifier 120, the example audio output driver 105 of FIG. 1 accepts any type of control signal ENABLE_OUT 130 (e.g., a digital control signal). For example, when the ENABLE_OUT signal 130 transitions to a logical high (e.g., 1.5 V), the amplifier 120 is powered on, and when the ENABLE_OUT signal 130 transitions to a logical low (e.g., 0 V), the amplifier 120 is powered off.

To provide a common-mode voltage V_{cmo} 135 used by the example amplifier 120 to generate the output 125, the example audio output driver 105 of FIG. 1 includes an amplifier controller 140. The example amplifier controller 140 of FIG. 1 may, in some examples, hold the common-mode voltage V_{cmo} 135 at substantially zero volts to prevent the occurrence of a voltage spike at the output 125 of the amplifier 120 when the amplifier is powered on and/or powered off. After the example amplifier 120 is turned on, the example amplifier controller 140 digitally adjusts, controls and/or changes (e.g., ramps) the common-mode voltage V_{cmo} 135 from substantially zero volts to the nominal common-mode voltage (e.g., 1.35 V) of the amplifier 120. Likewise, the amplifier controller 140 ramps the common-mode voltage V_{cmo} 135 from the nominal common-mode voltage to substantially zero, and then may hold the common-mode voltage V_{cmo} 135 at substantially zero volts while the amplifier 120 is powered off. The example amplifier controller 140 of FIG. 1 controls and/or changes the common-mode voltage V_{cmo} 135 in a substantially linear manner. However, the amplifier controller 140 could, additionally or alternatively, change the common-mode voltage V_{cmo} 135 along any type of curved slope. The slope α (i.e., rate of change) of the ramp is chosen and/or selected to control and/or limit the amplitude of the output voltage spike(s) that may occur as the common-mode voltage V_{cmo} 135 is adjusted. For example, if the ramp of the common-mode voltage V_{cmo} 135 occurs over 270 milliseconds (mS), output voltage spikes can be reduced to less than 1 mV, thereby becoming imperceptible to a user of the audio output driver 105. The example amplifier controller 140 of FIG. 1 may be controlled and/or programmed (e.g., digitally) to adjust the time duration of the ramp of the common-mode voltage V_{cmo} 135.

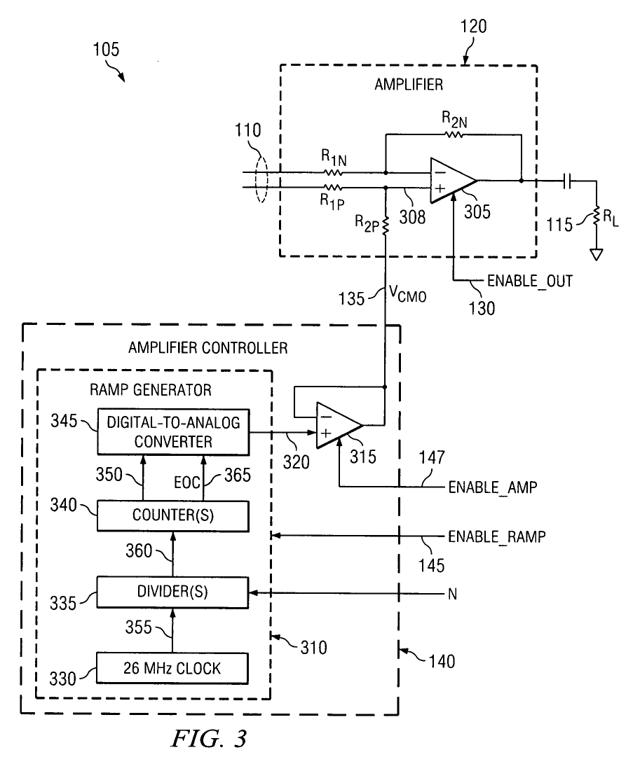

As described below in connection with FIGS. 3, 4 and 6, the common-mode voltage ramping performed by the example amplifier controller 140 is implemented digitally and, thus, the performance and/or characteristics of the circuits and apparatus described herein are substantially independent of device properties, process variations, and/or temperature variations. Moreover, the amplifier controller 140 may be controlled digitally to allow the common-mode voltage ramp up time to be programmed to facilitate different audio device specifications. Additionally, in some examples, the common-mode voltage ramp up performed by the amplifier controller 140 is independent of the impedance of the load 115.

To enable the example amplifier controller 140, the example audio output driver 105 of FIG. 1 accepts any type of control signal ENABLE_RAMP 145 (e.g., a digital control signal) and any type of control signal ENABLE_AMP 147 (e.g., a digital control signal). For example, when the ENABLE_RAMP signal 145 transitions to a logical high (e.g., 1.5 V), the amplifier controller 140 ramps the common-mode voltage V_{cmo} 135 from substantially zero to the nominal common-mode voltage (e.g., 1.35 V). Likewise, when the ENABLE_RAMP signal 145 transitions to a logical low (e.g., 0 V), the amplifier controller 140 ramps the common-mode voltage V_{cmo} 135 to substantially zero. When ENABLE_AMP 147 is a logical high (e.g., 1.5 V), the amplifier controller 140 is powered on and, thus, able to hold the common-mode voltage V_{cmo} 135 at zero volts while the amplifier 120 is being powered on and/or powered off.

The example amplifier 120 and the example amplifier controller 140 of FIG. 1 are implemented within a single integrated circuit (IC). However, the amplifier 120 and/or the amplifier controller 140 may be implemented by any number and/or type(s) of discrete and/or separate device(s), component(s) and/or IC(s).

In the illustrated example of FIG. 1, an impedance 150, a capacitor 155 and the load 115 are discrete components selected by, for example, based upon the particular audio device in which the amplifier 120 is to be used (e.g., a cellular telephone). The control signals 130, 145 and 147 may be controlled via, for example, a controller, a processor, and/or a programmable logic device (PLD). As illustrated in FIG. 2, to power on the example audio output driver 105 of FIG. 1, the ENABLE_AMP signal 147 is asynchronously and/or synchronously controlled to go to a logical high (e.g., 1.5 V) before the ENABLE_OUT signal 130 is asynchronously and/or synchronously controlled to go to a logical high (e.g., 1.5 V) to allow the amplifier controller 140 to ensure that the common-mode voltage V_{cmo} 135 and/or the output 125 are substantially zero before the amplifier 120 is powered on. After the amplifier 120 is powered on, the ENABLE_RAMP signal 145 is asynchronously and/or synchronously controlled to go to a logical high (e.g., 1.5 V), and the amplifier controller 140 ramps the common-mode voltage V_{cmo} 135 as described above. Likewise, to power off the audio output driver 105, the ENABLE_RAMP signal 145 is asynchronously and/or synchronously controlled to go to a logical low (e.g., 0 V) before the ENABLE_OUT signal 130 so that the amplifier controller 140 can ramp the common-mode voltage V_{cmo} 135 to substantially zero before the amplifier 120 is powered off by the ENABLE_OUT signal 130. Once the common-mode voltage V_{cmo} 135 has been ramped down and the amplifier 120 powered off, the ENABLE_AMP signal 147 may be asynchronously or synchronously controlled to go to a logical low (e.g., 0 V). The time period over which the amplifier controller 140 ramps the common-mode voltage V_{cmo} 135 may also be controlled and/or selected to suit the needs of a particular application (e.g., device). For example, a controller, a processor, and/or a PLD may write one or more digital control bits to the amplifier controller 140 to adjust the time period over which the amplifier controller 140 ramps the common-mode voltage V_{cmo} 135.

While in the illustrated examples described herein the ENABLE_OUT 130, ENABLE_RAMP 145 and ENABLE_AMP 147 control signals are provided to the audio output driver 105 as separate control signals, persons of ordinary skill in the art will readily appreciate that the audio output driver 105 may be implemented using fewer control signals (e.g., one). For example, the audio output driver 105 could implement any type of logic that generates ENABLE_OUT 130, ENABLE_RAMP 145 and/or ENABLE_AMP 147 control signals based on a single control signal (e.g., ENABLE_DRIVER) provided to the audio output driver 105.

Subsequent to the time 205 that the ENABLE_RAMP control signal 145 is controlled to go to a logical high (e.g., 1.5 V), the amplifier controller 140 starts ramping the common-mode voltage V_{cmo} 135 from 0 V towards 1.35 V along a substantially linear curve. As the common-mode voltage V_{cmo} 135 increases, the output signal 125 of the amplifier begins rising and eventually reaches the steady-state common-mode voltage (e.g., 1.35 V). Likewise, due to the increasing the common-mode voltage V_{cmo} 135, the load voltage V_{load} 118 experiences a momentary voltage spike 210 having a peak amplitude of αR_{L}C before settling back to zero, where α is the slope of the ramp of the common-mode voltage V_{cmo} 135. The voltage spike 210 can be further characterized by a value τ that represents the rate of increase of the voltage spike 210. The value of τ can approximated by EQN (1) below, where Rₒₙ is the output impedance of the amplifier 120.

$$τ = \frac{α {R}_{L}}{{R}_{L} + {R}_{s} + {R}_{ON}} \qquad EQN ( 1 )$$

The values αR_{L}C and τ affect the perceptibility of the voltage spike 210. In general, given values of R_{L}, C, a desired maximum amplitude αR_{L}C, and a maximum rise speed τ of the voltage spike 210, the slope a of the ramp of the common-mode voltage V_{cmo} 135 can be designed and/or computed. In general, for a lower value of α (i.e., a smaller slope and/or rate-of-change), a smaller voltage spike 210 occurs. However, in many instances the slope α can not be made arbitrarily small as a longer ramp delays the ability of the amplifier 120 to start driving the audio input signal 110 into the load 115. As illustrated in FIG. 2, because the common-mode voltage V_{cmo} 135 has been ramped up, the example voltage spike 210 is substantially smaller and/or substantially less perceptible to a user of the audio output driver 105 than if the common-mode voltage V_{cmo} 135 had been allowed to increase using, for example, a step-function.

FIG. 3 is a schematic illustration of an example manner of implementing the example audio output driver 105 of FIG. 1. To amplify the input signal 110, the example amplifier 120 of FIG. 3 includes an amplifier 305, and four resistors R_{1P}, R_{2P}, R_{1N} and R_{2N} that determine the gain implemented by the amplifier 305. The example resistors R_{1N} and R_{1P} of FIG. 3 have substantially the same impedances. Likewise, the example resistors R_{2N} and R_{2P} of FIG. 3 have substantially the same impedances. The ratio of R_{2N} to R_{1N} determines the gain of the amplifier 305. The example resistor R_{2P} is used by the example amplifier 120 of FIG. 2 to couple the common-mode voltage V_{cmo} 135 to the non-inverting input terminal 308 of the amplifier 305 and, thus, into the load 115.

To generate the common-mode voltage V_{cmo} 135, the example amplifier controller 140 of FIG. 2 includes a ramp generator 310 and any type of amplifier 315. The example ramp generator 310 generates a ramp signal 320 that the example amplifier 315 amplifies and/or buffers to form the common-mode voltage V_{cmo} 135. As illustrated in FIG. 3, the ENABLE_AMP control signal 147 powers on (e.g., enables) the amplifier 315, and the ENABLE_RAMP control signal 145 causes the ramp generator 310 to ramp the common-mode voltage V_{cmo} 135.

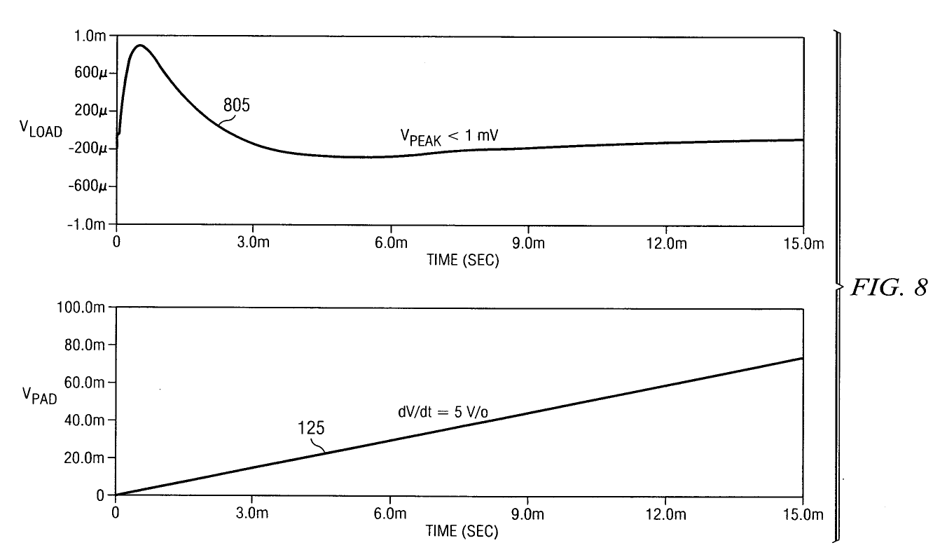

To generate the ramp signal 320, the example ramp generator 310 of FIG. 3 includes any type of clock source 330, any type and/or number of dividers 335, any type and/or number of counters 340 and any type of digital-to-analog converter (DAC) 345. Collectively, the example clock source 330, the example divider 335 and the example counter 340 of FIG. 3 create a sequence of digital values 350 (e.g., {0, 1, 2, 3, . . . } and/or {1023, 1022, 1021, . . . }). The sequence of digital values 350 is converted by the example DAC 345 of FIG. 3 to form the analog ramp signal 320. For example, if the digital values 350 represent the sequence {0, 1, 2, 3, . . . }, the ramp signal 320 created by the DAC 345 causes the common-mode voltage V_{cmo} 135 to be ramped from substantially zero to the nominal common-mode voltage (e.g., 1.35 V). An example DAC 345 accepts ten-bit input values 350 and is implemented using a resistor string (e.g., ladder) topology. An example manner of implementing the DAC 345 is described below in connection with FIG. 7.

The example clock source 330 of FIG. 3 is a 26 Million cycles per second (MHz) clock source commonly used in, for example, cellular telephones. The example divider 335 of FIG. 3 divides the clock signal 355 generated by the clock source by a factor of N. In the illustrated example of FIG. 3, the value of N is restricted to powers of 2 to reduce the complexity of the divider 335. For example, the divider 335 may be implemented as a chain of flip-flops, where the value of N selects which flip-flop of the chain determines the output 360 of the divider 335. The value of N may be written to and/or programmed into the divider 335 and/or, more generally, the amplifier controller 140 via any number of control bits and/or words. The value of N controls the duration of the ramp of the common-mode voltage V_{cmo} 135. A larger value of N results in a longer ramp duration. For example, when N is equal to 2̂9, a 20 msec ramp of the common-mode voltage V_{cmo} 135 is performed by the amplifier controller 140.

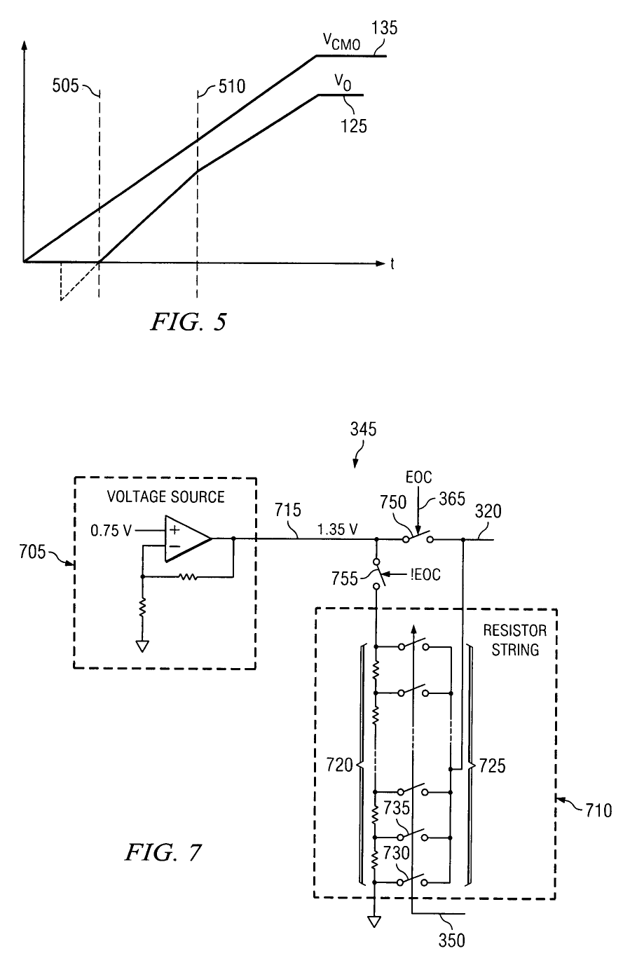

The example counter 340 of FIG. 3 counts edges of the output 360 of the divider 335. For example, at each rising edge of the counter input signal 360, the example counter 340 increments or decrements the digital value 350, depending on whether the common-mode voltage V_{cmo} 135 is being ramped up or ramped down. When the common-mode voltage V_{cmo} 135 is being ramped up, the counter 340 counts from 0 to 1023 (i.e., 0x3FF), and when the common-mode voltage V_{cmo} 135 is being ramped down, the counter 340 counts from 1023 to 0. The example counter 340 of FIG. 3 also generates a control signal EOC (end-of-count) 365 that indicates whether the counter 340 is currently counting (e.g., EOC=0 V), or has reach a terminal count value (e.g., 0 or 1023) and has stopped counting (e.g., EOC=1.5 V). As described below in connection with FIGS. 5A and 7, the EOC control signal may be used to reduce glitches due to voltage offsets in an audio device and/or to disable the DAC 345 when a ramp of the common-mode voltage V_{cmo} 135 has been completed.

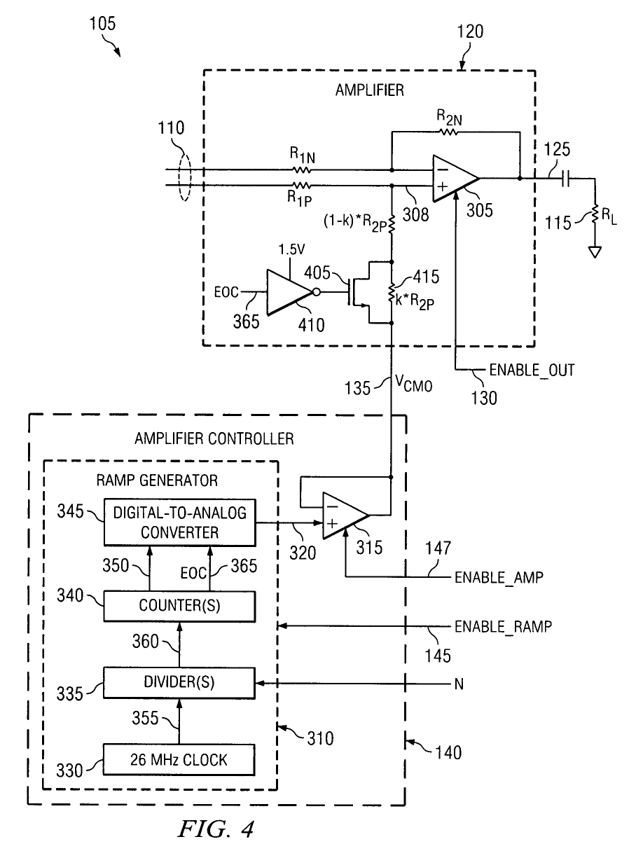

FIG. 4 is a schematic illustration of another example manner of implementing the example audio output driver 105 of FIG. 1. Portions of the example audio output driver 105 of FIG. 4 are identical to those discussed above in connection with FIG. 3 and, thus, the descriptions of those portions are not repeated here. Instead, identical elements are illustrated with identical reference numerals in FIGS. 3 and 4, and the interested reader is referred back to the descriptions presented above in connection with FIG. 3 for a complete description of those like-numbered elements.

To reduce output glitches due to, for example, voltage offsets between the amplifier 120 and other components of an audio device (e.g., an audio DAC used to convert a digital audio signal to form the analog audio signal 110), the example amplifier 120 of FIG. 4 includes a switch 405. The example switch 405 of FIG. 1 is implemented as an NMOS transistor or switch with the gate voltage of the switch 405 supplied by an inverting amplifier 410 having as its input the EOC signal 365 generated by the example counter 340. When the EOC control signal 365 is a logical high (e.g., 1.5 V indicating that the counter 340 is not currently counting), the switch 405 open. When the EOC control signal 365 is a logical low (e.g., 0 V indicating that the counter 340 is currently counting), the gate voltage of the switch 405 is 1.5 V and the common-mode voltage V_{cmo} 135 controls whether and/or how much the switch 405 is open or closed. When the counter 340 is counting and the common-mode voltage V_{cmo} 135 is small (e.g., near 0 V), the switch 405 is closed (i.e., conducting), thereby, shorting out a resistor 415 that is connected in parallel with the switch 405. As the common-mode voltage V_{cmo} 135 is ramped up, the switch 405 is progressively driven into its cut-off region and the switch 405 gradually opens. As the switch 405 gradually opens, the collective impedance value of the switch 405 and the resistor 415 gradually approaches the impedance of the resistor 415. Likewise, as the common-mode voltage V_{cmo} 135 decreases, the switch 405 is progressively driven out of its cut-off region and the switch 405 gradually closes.

In the illustrated example of FIG. 4, the impedance of the resistor 415 is a fraction k (e.g., 25%) of the impedance of the example resistor R_{2P} of FIG. 3. When the resistor 415 is wholly or partially shorted out by the switch 405, the common-mode voltage V_{cmo} 135 is coupled to the input 308 of the amplifier 305 via an impedance that is less than R_{2P}. Accordingly, the output Vₒ 125 of the amplifier 305 is driven to a value that is less than zero. The change in the output Vₒ 125 of the amplifier 305 due to decreasing the impedance of R_{2P} can be expressed mathematically as

$$Δ {V}_{o} = - \frac{{kR}_{2 P}}{{R}_{1 P} + ( 1 - k ) {R}_{2 P}} {V}_{cmo} . \qquad EQN ( 2 )$$

As illustrated in FIG. 5, because the output Vₒ 125 of the example amplifier 305 of FIG. 4 is constrained by its circuit design from taking on negative values, the output Vₒ 125 of the amplifier 305 will be held at substantially zero volts until a time t 505 when the common-mode voltage V_{cmo} 135 is large enough that the output Vₒ 125 is able to begin rising above zero volts. As the common-mode voltage V_{cmo} 135 continues to rise, the output Vₒ 125 also continues rising. When, the common-mode voltage V_{cmo} 135 becomes large enough at a time 510 (e.g., V_{cmo}>1.5 V−V_{threshold}, where V_{threshold} is the cut-off region threshold of the switch 405 (e.g., 0.7 V)), the switch 405 begins to gradually open. The switch 405 continues opening while the common-mode voltage V_{cmo} 135 rises. As the switch 405 opens, the slope of the output Vₒ 125 curve changes because the effective impedance coupling the common-mode voltage V_{cmo} 135 to the amplifier 305 changes. Likewise, as the common-mode voltage V_{cmo} 135 is ramped down, the output Vₒ 125 of the amplifier 305 will decrease until the common-mode voltage V_{cmo} 135 becomes small enough to hold the output Vₒ 125 at substantially zero volts.

Persons of ordinary skill in the art will readily appreciate that while in the example audio output driver 105 illustrated in FIG. 4 the example switch 405 is shown together with the example amplifier 120, the switch 405 may be implemented together with the example amplifier controller 140.

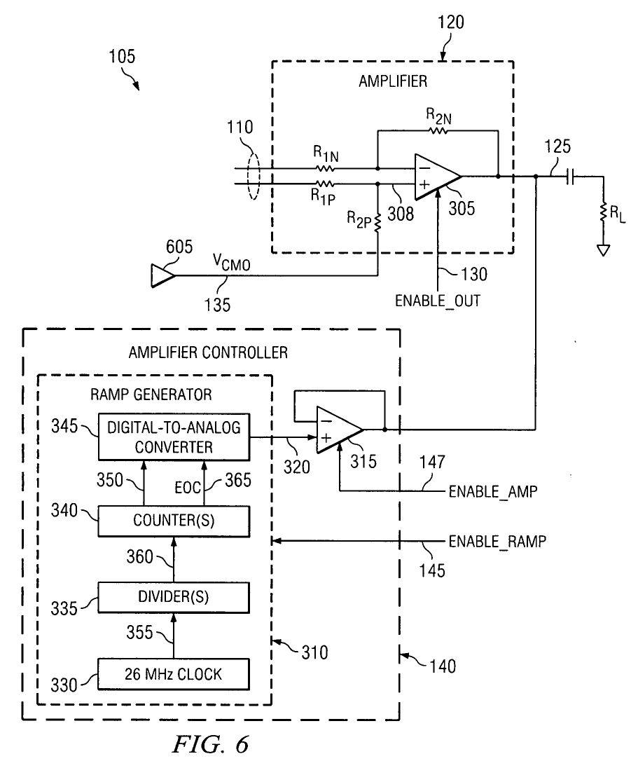

FIG. 6 is a schematic illustration of another example manner of implementing the example audio output driver 105 of FIG. 1. Portions of the example audio output driver 105 of FIG. 6 are identical to those discussed above in connection with FIG. 3 and, thus, the descriptions of those portions are not repeated here. Instead, identical elements are illustrated with identical reference numerals in FIGS. 3 and 6, and the interested reader is referred back to the descriptions presented above in connection with FIG. 3 for a complete description of those like-numbered elements.

In the example audio output driver 105 of FIG. 6, the example amplifier controller 140 directly drives the output 125 of the amplifier 120 rather than controlling the common-mode voltage V_{cmo} 135 of the amplifier 120. To supply the common-mode voltage V_{cmo} 135, the example audio output driver 105 of FIG. 6 includes an additional amplifier and/or voltage source 605. Using any logic, circuit(s) and/or device(s), the example amplifier and/or voltage source 605 provides the common-mode voltage V_{cmo} 135 for the amplifier 120.

The example audio output driver 105 of FIG. 6 may be used by first controlling the amplifier controller 140 to ramp the amplifier output 125. Once the output voltage 125 has been ramped, the amplifier 120 can be enabled without causing significant pops, clicks, and/or other glitches or transients on the output signal 125, and then the amplifier controller 140 disabled. Likewise, the amplifier controller 140 may be used to ramp down the amplifier 125 output after the amplifier 120 is disabled.

While example manners of implementing the example audio output driver 105 of FIG. 1 are illustrated in FIGS. 3, 4 and 6, the audio output driver 105 of FIG. 1 may be implemented using any number and/or type(s) of alternative and/or additional logic, devices, components, circuits, modules, interfaces, etc. Further, the logic, devices, components, circuits, modules, elements, interfaces, etc. illustrated in FIGS. 1, 3, 4 and/or 6 may be split, combined, re-arranged, eliminated and/or implemented in any other way. For example, the example amplifier 120 and the example amplifier controller 140 may be implemented together within a single IC. Additionally, any or all of the example amplifiers 120 and/or the example amplifier controllers 140 of FIGS. 1, 3, 4 and/or 6 may be implemented as any combination of firmware, software, logic and/or hardware. Moreover, the example audio output drivers 105 of FIGS. 1, 3, 4 and/or 6 may include additional logic, devices, components, circuits, interfaces and/or modules than those illustrated in FIGS. 1, 3, 4 and/or 6 and/or may include more than one of any or all of the illustrated logic, devices, components, circuits, interfaces and/or modules.

FIG. 7 is a schematic illustration of an example manner of implementing any or all of the example DACs 345 of FIGS. 3, 4 and 6. To generate an analog output voltage 320 in response to a digital counter output value 350, the example DAC 345 of FIG. 7 includes any type of voltage source 705 and any type of resistor string 710. The example voltage source 705 generates a voltage 715 corresponding to the nominal common-mode voltage of the amplifier 120 (e.g., 1.35 V).

The example resistor string 710 of FIG. 7 has a plurality of resistors 720 and switches 725 corresponding to possible output values 320 of the DAC 345. The plurality of resistors 720 of FIG. 7 implement a voltage divider with successively smaller voltage values occurring between resistors 720 that are located lower in the resistor string 710. Based on the counter output value 350, a corresponding one of a plurality of switches 725 is closed. For example, for an input value 350 of zero, a lowest switch 730 is closed, for an input value of 350 of one, a second lowest switch 735 is closed, etc.

To disable the resistor string 710 when the counter 340 is not counting (e.g., EOC=1.5 V), the example DAC 345 of FIG. 7 includes switches 750 and 755. When EOC is high (e.g., 1.5 V), switch 750 is closed and switch 755 is open, thereby bypassing the resistor string 710. When EOC is low (e.g., 0 V), switch 750 is open and switch 755 is open, thereby, enabling the resistor string 710. The resistor string 710 of FIG. 7 is disabled when the counter 340 is not counting to reduce noise from the DAC 345 from being introduced into the output 125 of the amplifier 120.

While an example manner of implementing any or all of the example DACs 345 of FIGS. 3, 4 and/or 6 is illustrated in FIG. 7, a DAC 345 may be implemented using any number and/or type(s) of alternative and/or additional logic, devices, components, circuits, etc. Further, the logic, devices, components, circuits, etc. illustrated in FIG. 7 may be split, combined, re-arranged, eliminated and/or implemented in any other way. For example, the resistor string 710 may be implemented using a resistor topology requiring fewer resistors 720. Additionally, the example DAC 345 may include additional logic, devices, components, circuits, etc. than those illustrated in FIG. 7 and/or may include more than one of any or all of the illustrated logic, devices, components, circuits.

FIG. 8 illustrates an example output waveform of the example audio driver of FIG. 1 when the audio amplifier is powered on. Illustrated in the lower graph of FIG. 8 is an output waveform 125 of the amplifier 120 as the amplifier controller 140 ramps the common-mode voltage V_{cmo} 135 from zero a nominal common-mode voltage (e.g., 1.35 V). The waveform 805 illustrated in the upper graph of FIG. 8 is obtained when the output 118 of the amplifier 120 corresponding to the lower graph is filtered using an audio weighting filter to represent how the load voltage 118 may be perceived by a human listener. As illustrated in the upper graph, the peak value of the waveform 805 is less than 1 mV and, thus, generally not perceptible by a human listener.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

1. An apparatus comprising:
an amplifier; and
an amplifier controller to digitally change a common-mode voltage of the amplifier to reduce an output noise of the amplifier.

2. An apparatus as defined in claim 1, wherein the amplifier controller is to substantially linearly ramp the common-mode voltage from a first voltage to a second voltage.

3. An apparatus as defined in claim 2, wherein the first voltage is substantially zero, and the second voltage is greater than the first voltage.

4. An apparatus as defined in claim 1, wherein the amplifier controller comprises:
a counter; and
a digital-to-analog converter to convert a counter output signal of the counter to a control signal, the control signal to change the common-mode voltage of the amplifier.

5. An apparatus as defined in claim 4, wherein the counter counts forward when the amplifier is powered-on, and the common-mode voltage changes from a first voltage to a second voltage, the second voltage being greater than the first voltage.

6. (canceled)

7. An apparatus as defined in claim 4, wherein the control signal is coupled by a resistor to an input of the amplifier to control the common-mode voltage of the amplifier.

8. An apparatus as defined in claim 4, further comprising a divider to create a counter input signal by dividing a clock signal by a value, the counter to count the counter input signal.

9. An apparatus as defined in claim 8, wherein the value used to divide the clock signal controls a rate of change of the common-mode voltage.

10. (canceled)

11. An apparatus as defined in claim 4, wherein the control signal is to control a switch to reduce an offset associated with the amplifier.

12. An apparatus as defined in claim 11, wherein the switch in a first state is to drive a common-mode voltage of the amplifier to a negative value.

13. (canceled)

14. An apparatus as defined in claim 1, wherein the output noise of the amplifier is an audible noise associated with at least one of powering on the amplifier

15. (canceled)

16. A circuit comprising:
a ramp generator to form a ramp signal; and
a first amplifier to convert the ramp signal to a common-mode voltage for a second amplifier.

17. A circuit as defined in claim 16, wherein the ramp signal is to change between a first voltage and a second voltage in a substantially linear manner.

18. A circuit as defined in claim 17, wherein the second voltage is substantially zero, and the first voltage is greater than the second voltage.

19. A circuit as defined in claim 16, wherein the ramp generator comprises:
a counter to count edges of a clock signal; and
a digital-to-analog converter to convert an output of the counter to form the ramp signal.

20. (canceled)

21. A circuit as defined in claim 19, wherein the digital-to-analog converter is bypassed when the counter reaches a terminal value.

22. A circuit as defined in claim 19, wherein the ramp generator further comprises a divider to create a counter input signal by dividing the clock signal by a value, and wherein the counter is to count edges of the counter input signal.

23. (canceled)

24. A circuit as defined in claim 16, further comprising a switch, wherein the switch is controlled to reduce an offset associated with the second amplifier.

25. (canceled)

26. A circuit as defined in claim 24, wherein the switch in a first state drives the common-voltage signal to a negative value.

27. A circuit as defined in claim 16, wherein the ramp generator controls the ramp signal to reduce an output noise of the amplifier.

28. (canceled)
